(19) United States
(12) Patent Application Publication
(10) Pub. No.: US 2016/0131327 A1
(43) Pub. Date: May 12, 2016

(54) LIGHT SOURCE MODULE AND LIGHTING DEVICE HAVING THE SAME

(71) Applicant: SAMSUNG ELECTRONICS CO., LTD, Suwon-si (KR)

(72) Inventors: Kyung Mi MOON, Suwon-si (KR); Tetsuo ARIYOSHI, Suwon-si (KR); Jong Pil WON, Yongin-si (KR); Seung Gyun JUNG, Suwon-si (KR); Jun CHO, Suwon-si (KR); Won Soo JI, Hwaseong-si (KR); Sung A CHOI, Yongin-si (KR)

(21) Appl. No.: 14/825,112

(22) Filed: Aug. 12, 2015

(30) Foreign Application Priority Data
Nov. 6, 2014 (KR) 10-2014-0153577

(51) Int. Cl. F21V 3/00; H01L 33/50; H01L 33/60

(52) U.S. Cl. CPC F21V 3/00; H01L 33/60; H01L 33/502; F21Y 2101/02

(57) ABSTRACT

There is provided a light source module including a light emitting device, and an optical device including a first surface disposed above the light emitting device and having a hollow recessed in a light emitting direction in a central portion through which an optical axis passes, and a second surface disposed to be opposite to the first surface and configured to refract light incident through the hollow to be emitted to the outside. The optical device includes a plurality of ridges disposed on the second surface and periodically arranged in a direction from the optical axis to an edge connected to the first surface.

### CROSS-REFERENCE TO RELATED APPLICATION

This application claims priority to Korean Patent Application No. 10-2014-0153577 filed on Nov. 6, 2014, with the Korean Intellectual Property Office, the entire contents of which are hereby incorporated by reference.

### TECHNICAL FIELD

The present disclosure relates to a light source module and a lighting device including the same.

### BACKGROUND

disclosure In the field of LED light sources, a dome-shaped lens (a so called primary lens) may be disposed on a package in a packaging process, in order to improve the light-emitting efficiency of the package. However, it may be somewhat difficult to combine such a lens with a package while performing a packaging process, such as a lead-frame or chip on module (COM) process, and to apply the process of combining the lens with the package due to relatively high manufacturing costs.

In order to implement a lighting module using such an LED light-source, a light-distribution control lens (a so called secondary lens) for collecting or distributing light may be included on a package in many cases.

Since such a secondary lens may have a size greater than that of the package, it may be easily mounted on the package. In addition, such a secondary lens may be easily fabricated. However, since a space corresponding to an air gap between the package and the secondary lens may be present, a refractive index may be rapidly changed. Accordingly, it may be difficult to implement a desired path of light, and light-emitting efficiency of a package may be decreased.

Accordingly, a light-emitting effect the same as light-emitting efficiency generally obtained through a primary lens is desirable. For example, a lighting module in which a full width at half maximum (FWHM) value is maintained while brightness is improved to almost twice that of a normal lighting module.

### SUMMARY

An aspect of the present disclosure may provide a light source module having improved light-emitting efficiency.

According to an aspect of the present disclosure, a light source module includes a substrate, at least one light-emitting device mounted on the substrate, and at least one optical device mounted on the substrate and covering the at least one light-emitting device. The optical device includes a first lens covering a light-emitting surface of the light-emitting device and a second lens covering the first lens.

The first lens may include a first surface disposed on the light-emitting surface of the light-emitting device and on which light is incident from the light-emitting surface, and a second surface connected to an edge of the first surface and protruding in a light-emitting direction. The second lens may include a third surface facing the light-emitting device and having a hollow accommodating the first lens in a center thereof, and a fourth surface disposed on the second surface, connected to an edge of the third surface, and emitting the light.

The first surface and the second surface may be disposed on a level corresponding to each other.

A cross-sectional area of the first surface may be the same as or greater than that of the light-emitting surface of the light-emitting device.

The first lens may be embedded in the second lens in the manner of filling the hollow, and integrated with the second lens.

The fourth surface may include a first curved surface recessed toward the hollow on an optical axis and having a concave surface and a second curved surface having a convex surface continuously extending from an edge of the first curved surface to an edge connected to the third surface.

At least one of the first lens and the second lens may contain a light-reflecting material.

A refractive index of the second lens may be the same as or greater than a refractive index of the first lens.

The at least one light-emitting device may include a package body having a reflective cup-shaped recess, an LED chip disposed in the recess, and a wavelength-converting layer filling the recess and sealing the LED chip.

The optical device may include a support protruding from the second lens.

The support may have a length corresponding to a height of the light-emitting device.

According to another aspect of the present disclosure, a light source module includes a substrate, at least one light-emitting device mounted on the substrate, at least one first lens mounted on the substrate and covering the at least one light-emitting device, and at least one second lens mounted on the substrate and covering the at least one first lens. The first lens is embedded in the second lens and integrated with the second lens.

The first lens may include a first surface disposed on the substrate, and a second surface connected to an edge of the first surface and protruding in a light-emitting direction. The second lens may include a third surface disposed on the substrate and including a hollow accommodating the first lens in a center thereof, a fourth surface disposed on the second surface and emitting light of the light-emitting device to the outside, and a fifth surface connecting edges of the third surface and the fourth surface and reflecting the light to the fourth surface.

The fifth surface may form an obtuse angle with respect to the third surface, and may be inclined with respect to the third surface.

The second lens may further include a reflective layer covering the fifth surface.

The fourth surface may be bulged in the light-emitting direction.

At least one of the hollow and the fourth surface may include ridges.

According to another aspect of the present disclosure, a lighting apparatus comprises a housing having an electrically connected structure, and at least one light-emitting module installed in the housing. The at least one light-emitting module comprises a substrate, at least one light-emitting device mounted on the substrate, and at least one optical device mounted on the substrate and covering the at least one light-emitting device. The optical device comprises a first lens covering a light-emitting surface of the light-emitting device and a second lens covering the first lens.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a perspective view illustrating a light source module according to an exemplary embodiment of the present disclosure;

FIG. 2 is a cross-sectional view of the light source module of FIG. 1;

FIGS. 3A and 3B are respectively a top plan view and a cross-sectional front elevation view illustrating a light-emitting device included in the light source module of FIG. 1;

FIGS. 4a and 4b are respectively a cross-sectional front elevation view and a top plan view illustrating an optical device in the light source module of FIG. 1;

FIG. 5 illustrates the CIE 1931 coordinate system provided to illustrate a wavelength-converting material usable in a light source module according to an exemplary embodiment of the present disclosure;

FIGS. 6A and 6B illustrate light distribution of a light source module according to a comparative example and a light source module according to an exemplary embodiment of the present disclosure, respectively;

FIGS. 7A and 7B illustrate illuminance distribution of a light source module according to comparative example and a light source module according to an exemplary embodiment of the present disclosure, respectively;

FIG. 8 is a perspective view illustrating a light source module according to an exemplary embodiment of the present disclosure;

FIG. 9 is a cross-sectional front elevation view of the light source module of FIG. 8;

FIGS. 10 to 14 are diagrams sequentially and schematically illustrating a method of fabricating a light source module according to an exemplary embodiment of the present disclosure;

FIGS. 15 to 17 are cross-sectional front elevation views illustrating various examples of LED chips applicable to a light source module according to an exemplary embodiment of the present disclosure;

FIG. 18 is an exploded perspective view illustrating a bulb type lighting apparatus according to an exemplary embodiment of the present disclosure;

FIG. 19 is an exploded partial perspective view illustrating an L-lamp type lighting apparatus according to an exemplary embodiment of the present disclosure;

FIG. 20 is an exploded perspective view illustrating a plate type lighting apparatus according to an exemplary embodiment of the present disclosure;

FIG. 21 is a block diagram schematically illustrating a lighting system according to an exemplary embodiment of the present disclosure;

FIG. 22 is a block diagram schematically illustrating a detailed configuration of a lighting unit of the lighting system of FIG. 21;

FIG. 23 is a flowchart illustrating a method of controlling the lighting system of FIG. 21; and

FIG. 24 is an exemplary view of use in which the lighting system of FIG. 21 is schematically implemented.

### DETAILED DESCRIPTION

Hereinafter, embodiments of the present disclosure will be described in detail with reference to the accompanying drawings.

The disclosure may, however, be exemplified in many different forms and should not be construed as being limited to the specific embodiments set forth herein.

Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements. Throughout this disclosure, directional terms such as “upper,” “upper (portion),” “upper surface,” “lower,” “lower (portion),” “lower surface,” or “side surface” may be used herein to describe the relationship of one element or feature to another, as illustrated in the drawings. It will be understood that such descriptions are intended to encompass different orientations in use or operation in addition to orientations depicted in the drawings.

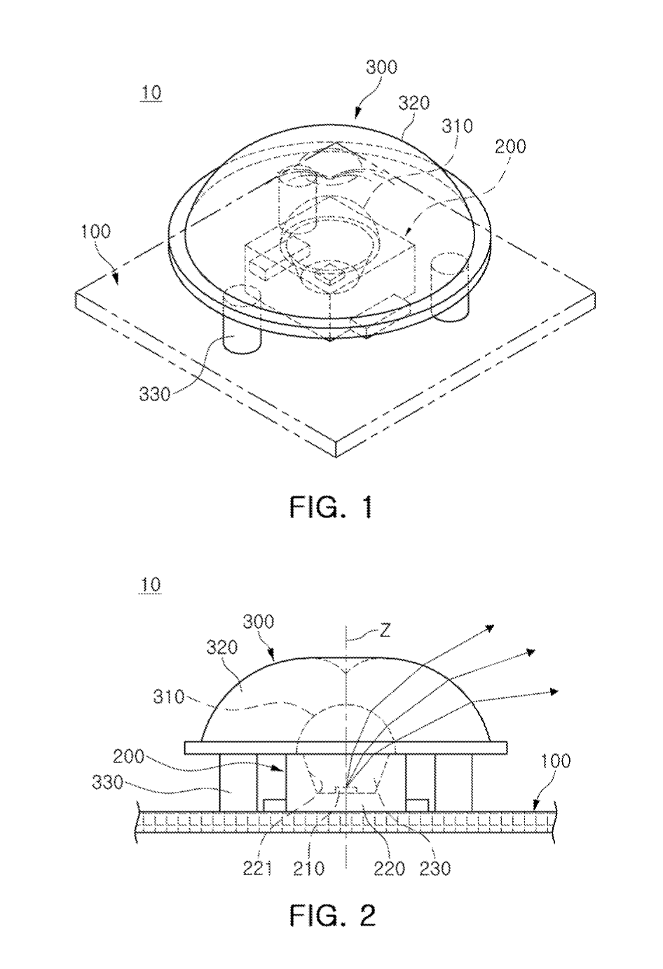

Referring to FIGS. 1 and 2, a light source module 10 according to an exemplary embodiment of the present disclosure may include a substrate 100, at least one light-emitting device 200 mounted on the substrate 100, and at least one optical device 300 mounted on the substrate 100.

The substrate 100 may correspond to a base structure supporting the light-emitting device 200 and the optical device 300, and the at least one light-emitting device 200 and the at least one optical device 300 may be fixed to the substrate 100.

The substrate 100 may include circuit wirings (not shown) electrically connected to the light-emitting device 200.

The substrate 100 may be an FR-4 type printed circuit board (PCB) or a flexible PCB that can be easily deformed, or may be formed of an organic resin material including epoxy, triazine, silicone, polyimide, or the like, or any other organic resin material. In addition, the substrate 100 may be formed of a ceramic material, such as SiN, AlN, or Al₂O₃, or a metal and metal compound, such as MCPCB or MCCL.

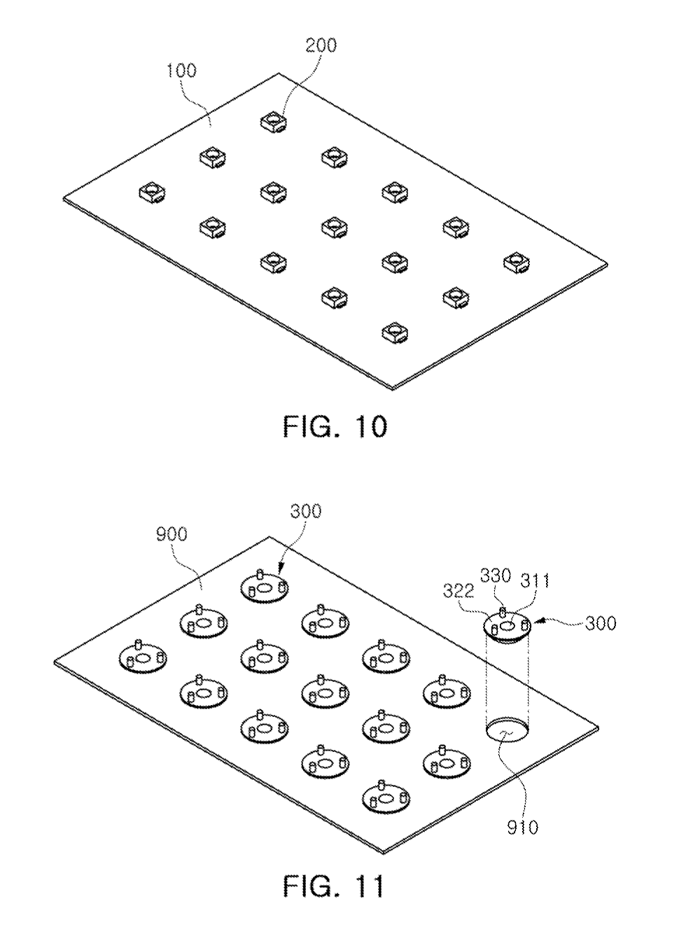

At least one light-emitting device 200 may be mounted on the substrate 100. In FIG. 1, a single light-emitting device 200 is mounted on the substrate 100, but the present disclosure is not limited thereto. For example, as illustrated in FIG. 10, a plurality of light-emitting devices 200 may be arranged on the substrate 100. The number of light-emitting devices 200 may be changed according to embodiments.

The light-emitting device 200 may be a photoelectric device that generates light of a predetermined wavelength through the application driving power applied from the outside thereto. For example, the light-emitting device 200 may include a semiconductor light-emitting diode (LED) chip including an n-type semiconductor layer, a p-type semiconductor layer, and an active layer disposed therebetween, and have a structure of a package including a package body in which the LED chip is installed.

The light-emitting device 200 may emit blue light, green light, or red light depending on a material contained therein or a combination with a phosphor, or emit white light, ultraviolet light, or the like.

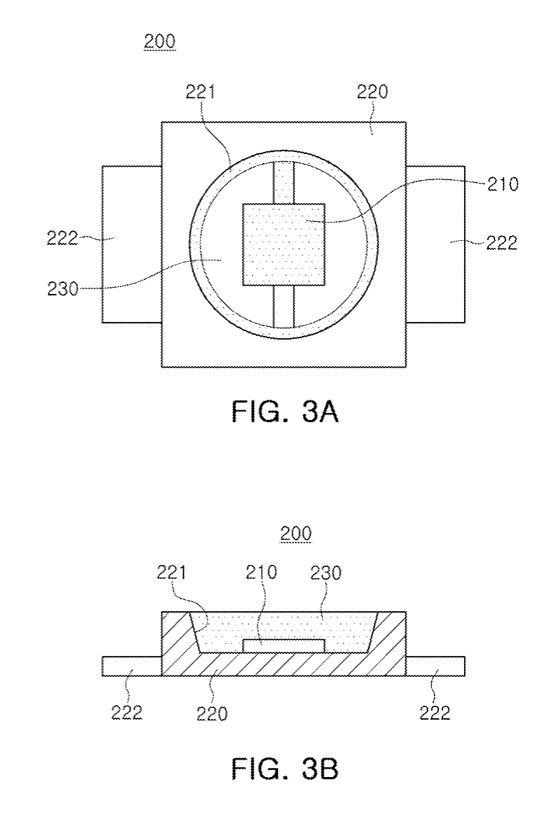

As shown in FIGS. 3A and 3B, the light-emitting device 200 may be configured with a package body 220 including a recess 221 having a reflective cup shape, an LED chip 210 mounted on the recess 221, and a wavelength-converting layer 230 filling the recess 221 and sealing the LED chip 210.

The package body 220 may be formed of a white molding compound having a high light reflectance, for example. The white molding compound may reflect light emitted from the LED chip 210 to increase the amount of light emitted to the outside. The white molding compound may include a thermosetting resin group or silicone resin group having high thermal resistance. In addition, a white pigment, a filler, a curing agent, a releasing agent, an antioxidant, an adhesion-improving agent, and the like may be added to a thermoplastic resin group. As another example, the package body 220 may be formed of FR-4, CEM-3, an epoxy material, or a ceramic material. As a further example, the package body 220 may be formed of a metal material such as Al.

The package body 220 may include a lead frame 222 to be electrically connected to an external power source. The lead frame 222 may be formed of a material having high electric conductivity, for example, a metal material such as Al or Cu. When the package body 220 is formed of a metal material, an insulating material (not shown) may be interposed between the package body 220 and the lead frame 222.

The lead frame 222 may be exposed on a bottom surface of the recess 221 of the package body 220, wherein the LED chip 210 is mounted on the bottom surface of the recess 221. In addition, the LED chip 210 may be electrically connected to the exposed lead frame 222.

A cross-sectional area of the recess 221 exposed on a top surface of the package body 220 may be larger than an area of the bottom surface of the recess 221. Here, the cross-sectional area of the recess 221 exposed on the top surface of the package body 220 may be defined as a light-emitting surface of the light emitting device 200.

Meanwhile, the LED chip 210 may be sealed by the wavelength-converting layer 230 formed in the recess 221 of the package body 220. The wavelength-converting layer 230 may include a wavelength-converting material.

The wavelength-converting material may include, for example, at least one kind of phosphor excited by light generated in the LED chip 210 to emit light having a different wavelength. Thus, light having different colors including white light may be emitted.

For example, when the LED chip 210 emits blue light, white light may be emitted by mixing phosphors having yellow, green, and red or orange colors. As another example, the LED chip 210 may be configured to include at least one of light emitting devices emitting purple, blue, red, and infrared light. In this case, the LED chip 210 may control color rendering index (CRI) to be in the range from a level of a sodium lamp (CRI 40) to the level of sunlight (CRI 100), and generate a variety of levels of white light having color temperatures in the range of about 2000K to about 20,000K. In addition, the LED chip 210 may emit visible light having a purple, blue, green, red, or orange color, or infrared light as needed, and may control the color according to an environment or mood. In addition, the LED chip 210 may emit light having a specific wavelength to promote plant growth.

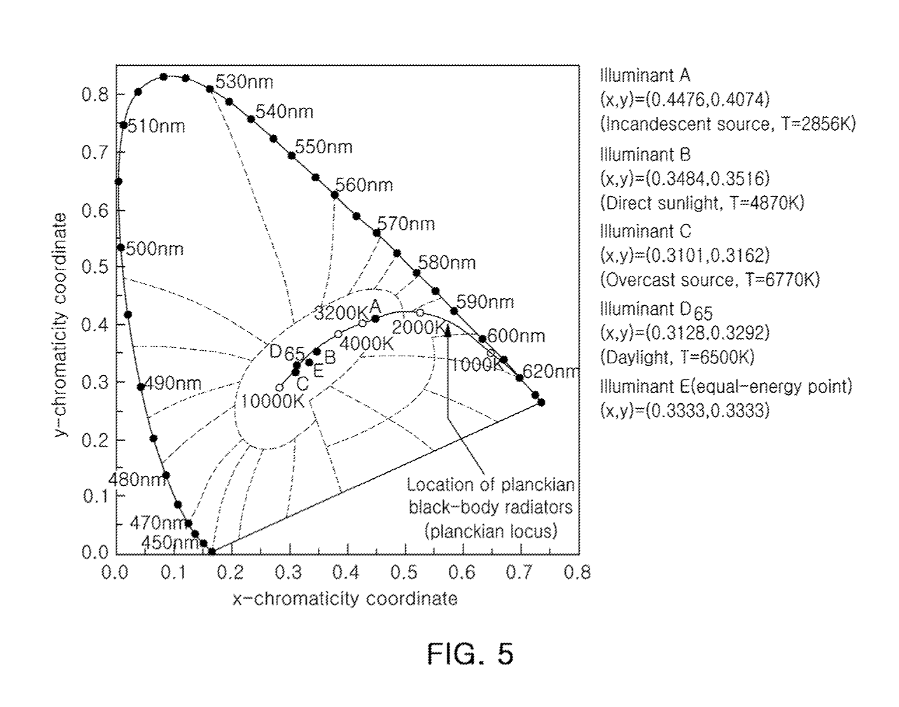

White light formed by a combination of a blue LED, and yellow, green, and red phosphors and/or green and red LED may have two or more peak wavelengths, and may be located on the line connecting (x, y) coordinates of (0.4476, 0.4074), (0.3484, 0.3516), (0.3101, 0.3162), (0.3128, 0.3292), (0.3333, 0.3333) in the CIE 1931 chromaticity diagram illustrated in FIG. 5. As another example, the white light may be located in a zone surrounded by the line and black body radiation spectrum. The color temperature of the white light may correspond to a range from about 2000K to about 20,000K.

The phosphor may have a compositional formula and color as follows.

Oxide group: yellow and green Y₃Al₅O₁₂:Ce, Tb₃Al₅O₁₂:Ce, Lu₃Al₅O₁₂:Ce

Silicate group: yellow and green (Ba,Sr)₂SiO₄:Eu, yellow and orange (Ba,Sr)₃SiO₅:Ce

Nitride group: green β-SiAlON:Eu, yellow La₃Si₆N₁₁:Ce, orange α-SiAlON:Eu, red CaAlSiN³:Eu, Sr₂Si₅N₈:Eu, SrSiAl₄N₇:Eu

Fluoride group: KSF-based red K₂SiF₆:Mn4+

The composition of the phosphor may be consistent with stoichiometry, and each element may be substituted by another element in each group of the periodic table.

For example, strontium (Sr) may be substituted by Ba, Ca, Mg, and the like in the alkaline earth (II) group, and Y may be substituted by Tb, Lu, Sc, Gd, and the like in the lanthanide group. In addition, Eu, an activator, and the like may be substituted by Ce, Tb, Pr, Er, Yb, and the like according to a preferred energy level. The activator may be used alone, or a coactivator may be further included in order to change characteristics.

In addition, a material such as a quantum dot (QD) may be used as an alternative material for phosphors, or phosphors and the QD may be used alone or mixed.

The QD may have a structure consisting of a core (diameter of about 3 to 10 nm), such as CdSe and InP, a shell (thickness of about 0.5 to 2 nm), such as ZnS and ZnSe, and a ligand for stabilizing the shell and core, and implement a variety of colors according to the size.

At least one optical device 300 may be mounted on the substrate 100 and cover at least one light-emitting device 200. The number of the optical device 300 may correspond to the number of the light-emitting device 200. In addition, each optical device 300 may be disposed in a location corresponding to a location of each light-emitting device 200 in a structure of covering the light-emitting device 200, and mounted on the substrate 100.

The optical device 300 may be disposed on the light-emitting device 200 to control a beam angle of light emitted from the light-emitting device 200. For example, the optical device 300 may include a wide beam angle lens spreading the light emitted from the light-emitting device 200 to implement a wide beam angle.

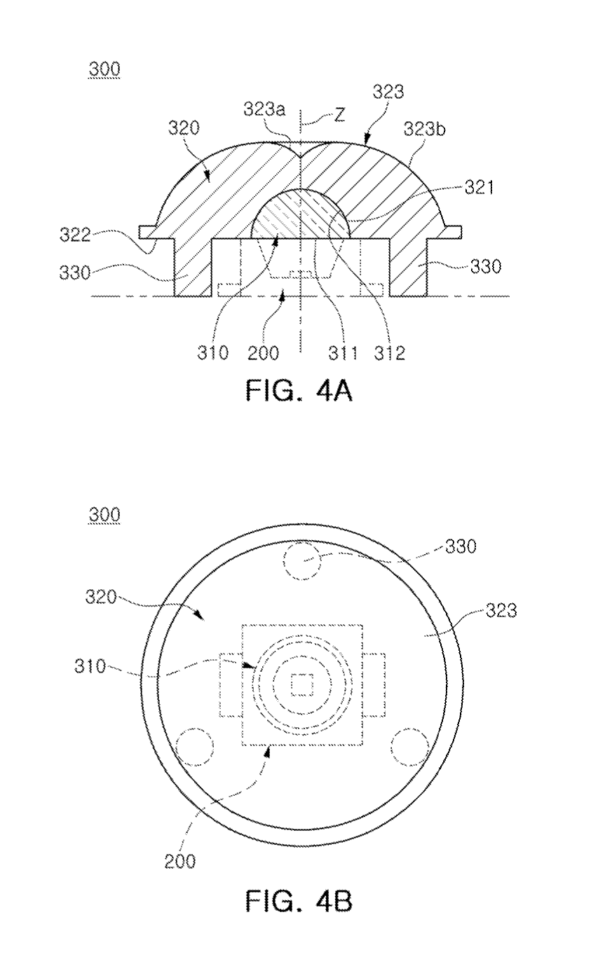

As illustrated in FIGS. 4A and 4B, the optical device 300 may include a first lens 310 covering the light-emitting surface of the light-emitting device 200, and a second lens 320 covering the first lens 310. The first and second lenses 310 and 320 may have an integrated structure.

The first lens 310 may cover the light-emitting device 200, and may be disposed to be in contact with an upper surface of the light-emitting device 200. The first lens 310 may be disposed on the light-emitting surface of the light-emitting device 200, and may include a first surface 311 to which light is incident from the light-emitting surface, and a second surface 312 connected to an edge of the first surface 311 and protruding in a light emitting direction.

The first surface 311 may correspond to a bottom surface of the first lens 310, and the first lens 310 may be disposed on the light-emitting device 200 in such a manner that the first surface 311 is in contact with the upper surface of the light-emitting device 200. The first surface 311 may have a flat circular-shaped horizontal cross-sectional structure overall. In addition, a cross-sectional area of the first surface 311 may be the same as or greater than that of the light-emitting surface of the light-emitting device 200.

In addition, the first surface 311 may be defined as an incident surface of the first lens 310 and, moreover, the optical device 300. Accordingly, light generated from the light-emitting device 200 may be incident from the light-emitting surface to the first lens 310 through the first surface 311.

The second surface 312 may be disposed opposite to the first surface 311. The second surface 312 is a light-emitting surface through which light entered through the first surface 311 is refracted and emitted to the outside, and corresponds to an upper surface of the first lens 310. The second surface 312 may have an overall dome shape, bulged upwardly, that is, in the light-emitting direction, from an edge connected to the first surface 311.

The second lens 320 may cover the first lens 310, and may be disposed on the light-emitting device 200, together with the first lens 310. The second lens 320 may include a third surface 322 facing the light-emitting device 200 and including a hollow 321 in the center of the third surface 322, in which accommodates the first lens 310, and a fourth surface 323 connected to an edge of the third surface 322, disposed on the second surface 312, and through which the light is emitted.

The third surface 322 may correspond to a bottom surface of the second lens 320, face the light-emitting device 200, and be disposed on the light-emitting device 200. In addition, the third surface 322 of the second lens 320 and the first surface 311 of the first lens 310 may define a bottom surface of the optical device 300. In this case, the third surface 322 may be at the same level as and coplanar with the first surface 311. The third surface 322 may have a flat circular-shaped horizontal cross-sectional structure overall, like the first surface 311.

The third surface 322 may include a hollow 321 recessed in a light-emitting direction in the center thereof through which an optical axis Z of the light-emitting device 200 passes. The hollow 321 may have a rotationally symmetrical structure with respect to the optical axis Z passing through the center of the second lens 320, and a surface of the hollow 321 may be defined as an incident surface on which light emitted from the light emitting device 200 is incident. Accordingly, light emitted to the outside from the light-emitting device 200 through the second surface 312 of the first lens 310 may pass through the hollow 321 to proceed to the inside of the second lens 320.

The hollow 321 may be open to the outside through the third surface 322. In addition, in the open hollow 321, the first lens 310 may be embedded in the second lens 320 in such a manner to fill the hollow 321 and form an integrated structure with the second lens 320.

Ridges for light scattering (not shown) may be formed on the surface of the hollow 321. Such ridges may be formed, for example, by performing caustic etching on the surface of the hollow 321.

The fourth surface 323 may be disposed opposite to the third surface 322. The fourth surface 323 is a light-emitting surface in which light entered through the hollow 321 is refracted and emitted to the outside, and corresponds to upper surfaces of the second lens 320 and the optical device 300.

The fourth surface 323 may be bulged in a light-emitting direction, that is, upwardly, overall in the form of a dome from an edge connected to the third surface 322, and a central portion through which the optical axis Z passes may be concavely recessed toward the hollow 321 to have an inflection point.

As illustrated in FIG. 4A, the fourth surface 323 may include a first curved surface 323a recessed along the optical axis Z toward the hollow 321 to have a concavely curved surface, and a second curved surface 323b extending continuously from an edge of the first curved surface 323a to the edge of the third surface 322 to have a convexly curved surface.

The first lens 310 and the second lens 320 may be formed of a resin material having translucency, for example, polycarbonate (PC), polymethylmethacrylate (PMMA), acrylic, and the like. In addition, the first lens 310 and the second lens 320 may be formed of a glass material, but is not limited thereto.

A refractive index of the second lens 320 may be the same as or greater than that of the first lens 310, and a refractive index of the first lens 310 may be the same as or greater than that of the wavelength-converting layer 230 of the light-emitting device 200. Accordingly, a refractive index of a medium through which light of the light-emitting device 200 passes may gradually change.

At least one of the first lens 310 and the second lens 320 may include a light-reflective material. As the light-reflective material, for example, at least one material selected from the group consisting of SiO₂, TiO₂, and Al₂O₃ may be included.

Such a light-reflective material may be contained in the range of about 3% to 15%. When the content of the light-reflective material is less than 3%, there is a problem in that a light-spreading effect is not obtained since light is not sufficiently spread. In addition, when the content of the light-reflective material is more than 15%, the amount of light emitted to the outside through the optical device 300 may be reduced, and thus light-extraction efficiency may be decreased.

The optical device 300 may be formed in such a way that a fluidal solvent is injected into a mold and solidified. For example, the second lens 320 may be formed by injection molding, transfer molding, compression molding, or the like, and the first lens 310 filling the hollow 321 may be formed by injecting the fluidal solvent into the hollow 321 using the second lens 320 as a mold and solidifying the fluidal solvent. The optical device 300 formed in such a method may have a structure in which the first lens 310 and the second lens 320 are integrally formed.

Otherwise, the first and second lenses 310 and 320 may be independently formed by injecting fluidal solvents into respective molds and solidifying the fluidal solvents. Then, the optical device 300 having a structure in which the first lens 310 and the second lens 320 are integrally formed may be formed by attaching the first lens 310 to the hollow 321 of the second lens 320 with an adhesive.

Meanwhile, the optical device 300 may further include a support 330 protruding from the second lens 320. The support 330 may protrude from the third surface 322 of the second lens 320 toward the light-emitting device 200, and at least two supports 330 may be included, for example. The support 330 may be integrally formed with the second lens 320 or attached to the third surface 322.

The support 330 may fix and support the optical device 300 when the optical device 300, for example, is installed on the substrate 100. That is, the optical device 300 may be installed on the substrate 100 through the support 330. In this case, the support 330 may have a length corresponding to a height of the light-emitting device 200.

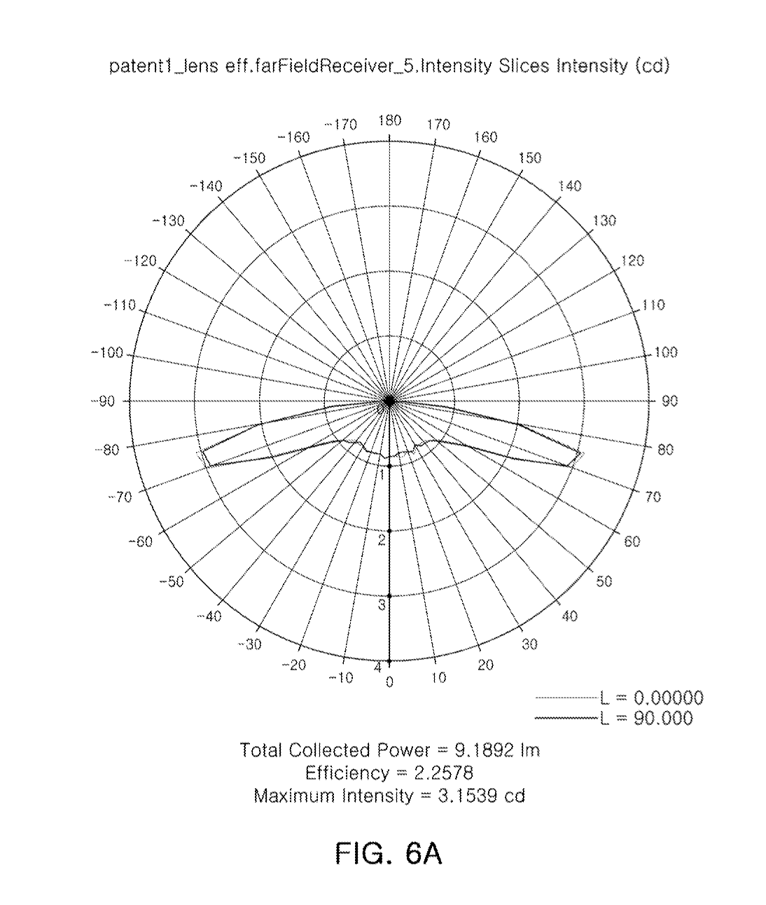

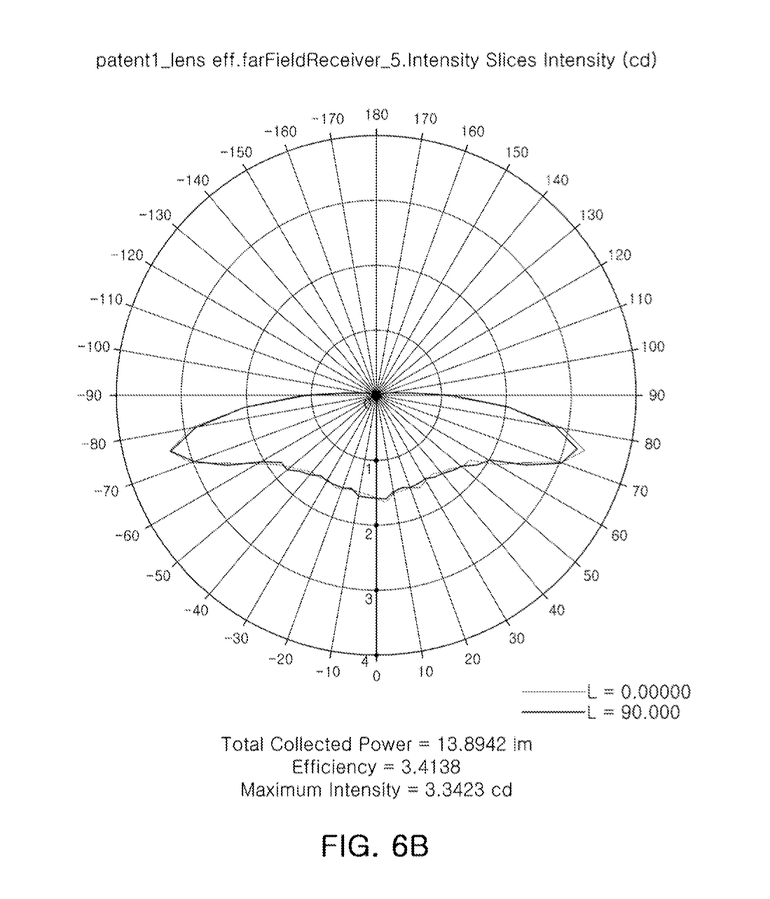

FIGS. 6A and 6B illustrate light distribution of a light source module according to a comparative example and a light source module according to an exemplary embodiment of the present disclosure, respectively.

The light source module according to the comparative example has a normal structure in which a secondary lens is disposed on a light-emitting device, and is different from a light source module 10 according to an exemplary embodiment of the present disclosure in that there is no the first lens 310. That is, although the overall structures of the light source modules in the exemplary embodiment and the comparative example are similar, the light source module 10 according to the exemplary embodiment of the present disclosure is different from the comparative example in that the optical device 300 has a dual-lens structure in which the second lens 320 and the first lens 310 are integrally formed.

Light distribution, illustrated in FIG. 6A, of the light source module according to the comparative example is similar overall to the light distribution, illustrated in FIG. 6B, of the light source module according to the exemplary embodiment of the present disclosure.

However, around the optical axis, an intensity of light of the light source module according to the exemplary embodiment of the present disclosure may be increased to almost twice an intensity of light of the light source module according to the comparative example. That is, the light source module according to the exemplary embodiment of the present disclosure may have an improved light-extraction efficiency compared to the light source module according to the comparative example.

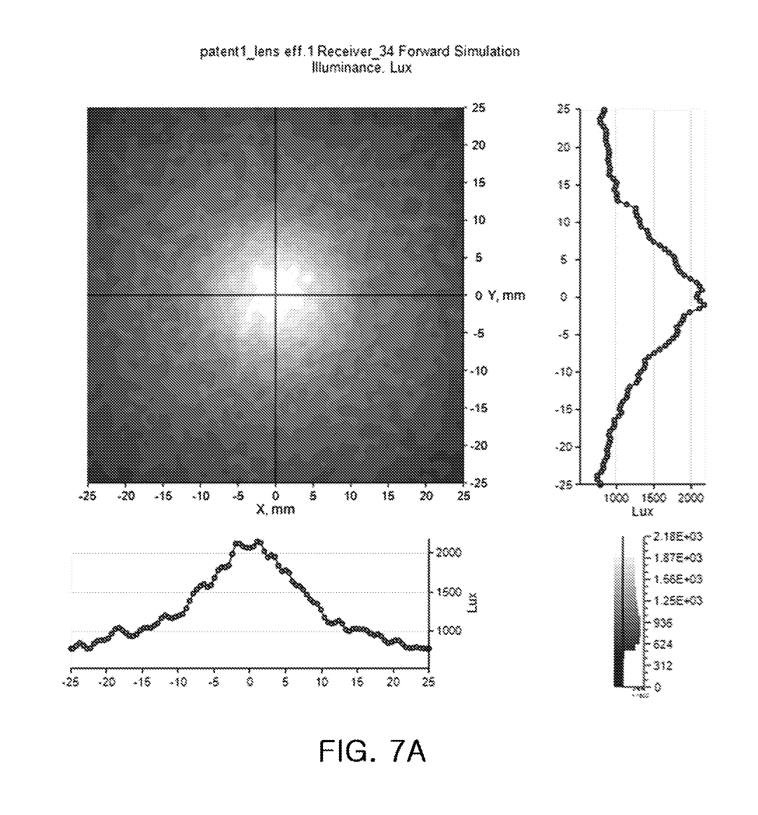

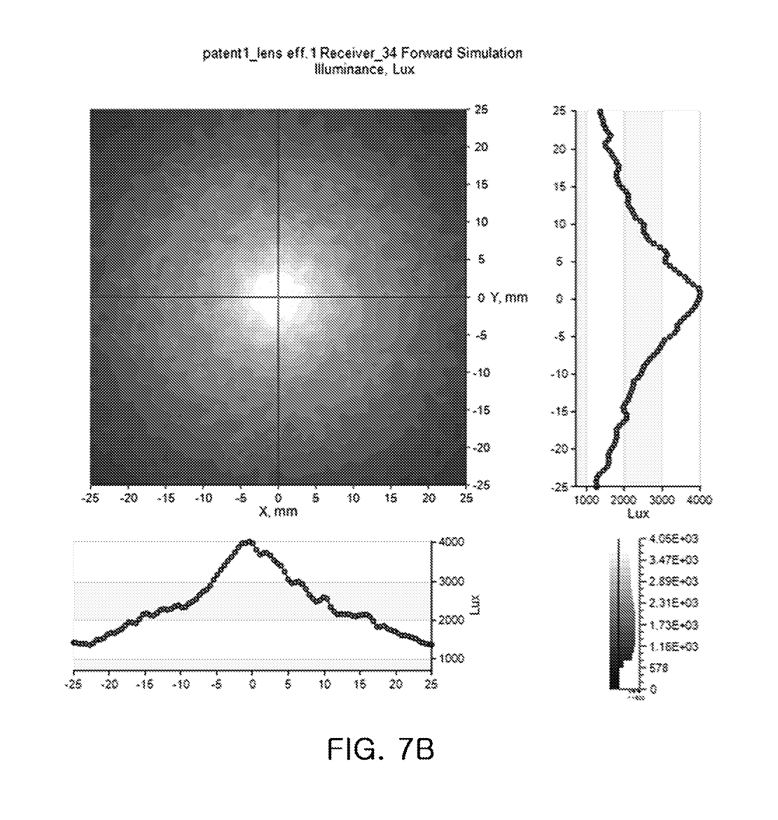

FIGS. 7A and 7B illustrate illuminance distribution of a light source module according to a comparative and a light source module according to an exemplary embodiment of the present disclosure, respectively. Luminance, illustrated in FIG. 7B, of the light source module according to the present disclosure increased to almost twice luminance, illustrated in FIG. 7A, of the light source module according to the comparative example, while maintaining a full width at half maximum (FWHM) value. That is, light-extraction efficiency may increase.

In the case of the light source module according to the comparative example, light generated from the light-emitting device may have a path of being incident to air having a relatively low refractive index and then incident to a lens having a high refractive index. That is, in a structure in which a refractive index is rapidly changed, some of light may not be incident to the lens or emitted to the outside through the lens due to, for example, total reflection or Fresnel reflection.

Since the light source module 10 according to the exemplary embodiment of the present disclosure has a structure in which the first lens 310 fills a space between the second lens 320 and the light-emitting device 200, the first lens 310 may function as a kind of buffer to mitigate changes in the refractive index.

Light of the light-emitting device 200 may have a path on which it is directly incident on the first lens 310, then incident on the second lens 320 from the first lens 310, and then emitted to the outside. Accordingly, compared to the light source module according to the comparative example, loss of light may be prevented. In addition, since light refracted and on the first lens 310 to be emitted is refracted again in the second lens 320 and finally emitted to the outside, wider and more uniform illuminance distribution can be implemented through three times of refraction (see FIG. 2).

In addition, a preferred path of light can be obtained using the difference in refractive indices between the first lens 310 and the second lens 320.

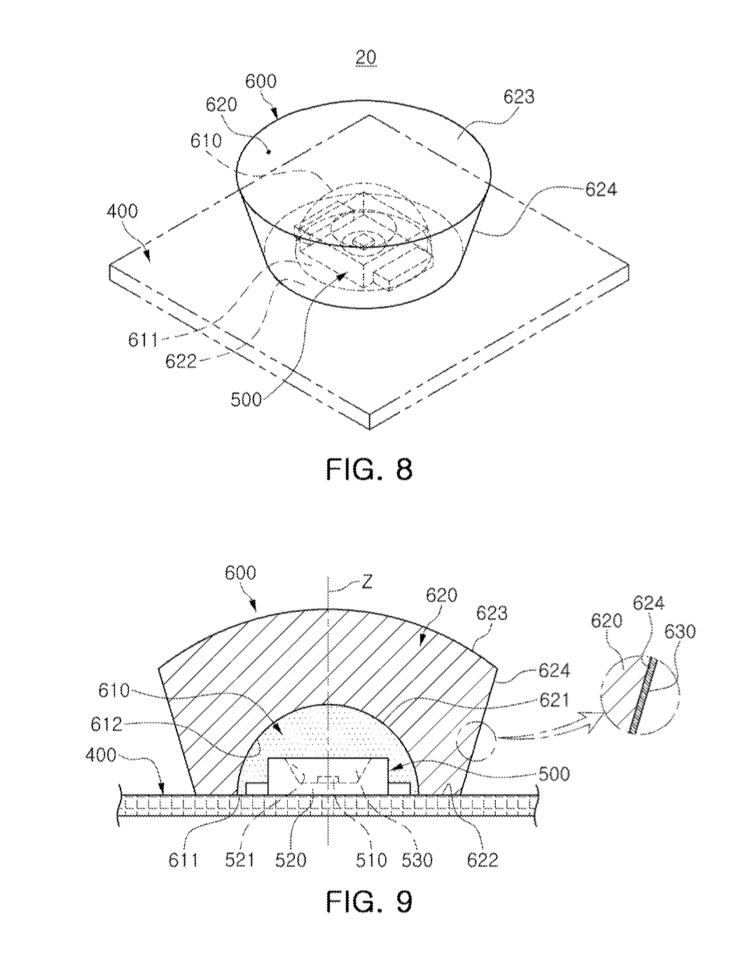

A basic structure of a light source module 20 according to the exemplary embodiment illustrated in FIGS. 8 and 9 may be substantially the same as the structure of the exemplary embodiment illustrated in FIGS. 1 to 4. However, since a structure of an optical device 600 is different from those illustrated in FIGS. 1 to 4, the structure of the optical device 600 will be mainly described, and descriptions duplicated from the exemplary embodiments described above will be omitted.

Referring to FIGS. 8 and 9, a light source module 20 according to the exemplary embodiment of the present disclosure may include a substrate 400, at least one light-emitting device 500 mounted on the substrate 400, and at least one optical device 600 mounted on the substrate 400.

The substrate 400 may correspond to a base structure supporting the light-emitting device 500 and the optical device 600, and the at least one light-emitting device 500 and the at least one optical device 600 may be fixed to the substrate 400.

The substrate 400 may be an FR-4 type printed circuit board (PCB) or a flexible PCB that can be easily deformed, or may be formed of an organic resin material including epoxy, triazine, silicone, polyimide, or the like, or any other organic resin material. In addition, the substrate 400 may be formed of a ceramic material, such as SiN, AlN, or Al₂O₃, or a metal and metal compound, such as MCPCB or MCCL.

At least one light-emitting device 500 may be mounted on the substrate 400. The number of light-emitting device 500 may be changed according to embodiments.

The light-emitting device 500 may be a photoelectric device that generates light of a predetermined wavelength by driving power applied from the outside. For example, the light-emitting device 500 may include a semiconductor LED chip including an n-type semiconductor layer, a p-type semiconductor layer, and an active layer disposed therebetween, and have a structure of a package including a package body in which the LED chip is installed.

As illustrated in FIG. 9, the light-emitting device 500 may include a package body 520 having a reflective cup-shaped recess 521, an LED chip 510 mounted on the recess 521, and a wavelength-converting layer 530 filling the recess 521 and sealing the LED chip 510.

A basic configuration and a structure of the light-emitting device 500 may be substantially the same as those of the light-emitting device 200 illustrated in FIG. 3. Accordingly, detailed descriptions thereof will be omitted.

At least one optical device 600 may be mounted on the substrate 400 to cover the at least one light-emitting device 500. The number of the optical devices 600 may correspond to the number of the light-emitting devices 500. In addition, each optical device 600 may be disposed in a location corresponding to a location of each light-emitting device 500 in a structure of covering the light-emitting device 500, and mounted on the substrate 400.

The optical device 600 may be disposed on the light-emitting device 500 to control a beam angle of light emitted from the light-emitting device 500. For example, the optical device 600 may include a condensing lens concentrating light emitted from the light-emitting device 500 to a predetermined area.

As illustrated in FIG. 9, the optical device 600 may include a first lens 610 covering the light-emitting device 500 and a second lens 620 covering the first lens 610, and the first and second lenses 610 and 620 may have an integrated structure.

The first lens 610 may cover and encapsulate the light-emitting device 500 and may be disposed on the substrate 400. The first lens 610 may include a first surface 611 disposed on the substrate 400, and a second surface 612 connected to an edge of the first surface 611 and protruding in a light emitting direction.

The first surface 611 may correspond to a bottom surface of the first lens 610, and the first lens 610 may be disposed on the substrate 400 in such a manner that the first surface 611 is in contact with an upper surface of the substrate 400. The first surface 611 may have a flat circular-shaped horizontal cross-sectional structure overall.

The second surface 612 may be disposed opposite to the first surface 611. The second surface 612 is a light-emitting surface through which light generated from the light-emitting device 500 is refracted and emitted to the outside, and corresponds to an upper surface of the first lens 610. The second surface 612 may have an overall dome shape, bulged upwardly, that is, in the light-emitting direction, from an edge connected to the first surface 611.

The first lens 610 may have a structure in which the light-emitting device 500 is embedded, and may be disposed on the substrate 400. Accordingly, light generated from the light-emitting device 500 may directly proceed to the inside of the first lens 610 to be emitted to the outside through the second surface 612. Accordingly, a portion of the inside of the first lens 610 interfacing with the light-emitting surface of the light-emitting device 500 may be defined as an incident surface of the first lens 610.

The second lens 620 may cover the first lens 610, and may be disposed on the substrate 400 together with the first lens 610. The second lens 620 may include a third surface 622 disposed on the substrate 400 and having a hollow 621 accommodating the first lens 610 in a center thereof, a fourth surface 623 disposed on the second surface 612 to emit light of the light-emitting device 500 to the outside, and a fifth surface 624 connecting edges of the third surface 622 and fourth surface 623 and reflecting the light to the fourth surface 623.

The third surface 622 may correspond to a bottom surface of the second lens 620 and may be disposed on the substrate 400. In addition, the third surface 622 may define a bottom surface of the optical device 600 together with the first surface 611 of the first lens 610. The third surface 622, like the first surface 611, may have a flat circular-shaped horizontal cross-sectional structure overall.

The third surface 622 may include the hollow 621 recessed in a light-emitting direction in the center thereof through which an optical axis Z of the light-emitting device 500 passes. The hollow 621 may have a rotationally symmetrical structure with respect to the optical axis Z passing through the center of the second lens 620, and a surface of the hollow 621 may be defined as an incident surface on which light emitted from the light emitting device 500 is incident. Accordingly, light emitted to the outside from the light-emitting device 500 through the second surface 612 of the first lens 610 may pass through the hollow 621 to proceed to the inside of the second lens 620.

The hollow 621 may be open to the outside through the third surface 622. In addition, in the open hollow 621, the first lens 610 may be embedded in the second lens 620 in such a manner to fill the hollow 621 and form an integrated structure with the second lens 620.

Ridges for light scattering (not shown) may be formed on the surface of the hollow 621. Such ridges may be formed, for example, by performing caustic etching on the surface of the hollow 621.

The fourth surface 623 may be disposed opposite to the third surface 622. The fourth surface 623 is a light-emitting surface in which light entered through the hollow 621 is refracted and emitted to the outside, and corresponds to upper surfaces of the second lens 620 and the optical device 600. The fourth surface 623 may be bulged in a light-emitting direction, that is, upwardly. In addition, ridges for light scattering may be formed on the fourth surface 623.

The fifth surface 624 may extend upwardly from the edge of the third surface 622, to be connected to the edge of the fourth surface 623, and correspond to a side surface of the optical device 600. The fifth surface 624 may be inclined to form an obtuse angle with respect to the third surface 622. Accordingly, the second lens 620 may have a structure in which a cross-sectional area thereof increases from the third surface 622 upwardly toward the fourth surface 623.

The fifth surface 624 may reflect light incident through the hollow 621 to the fourth surface 623. In addition, a light distribution area may be variously controlled by changing a slope with respect to the third surface 622.

Meanwhile, the second lens 620 may further include a reflective layer 630 covering the fifth surface 624. Thus, light reflection efficiency may be further improved. The reflective layer 630 may be formed as a metal thin-film layer. A material of the metal thin-film layer may be, for example, aluminum (Al), copper (Cu), silver (Ag), or the like, and may be formed on the fifth surface 624 by coating, deposition, or attachment using an adhesive. In addition, the reflective layer 630 may be formed of a resin containing a light-reflective material.

The first lens 610 and second lens 620 may be formed of a resin material having translucency, for example, PC, PMMA, and acrylic. In addition, the first lens 610 and the second lens 620 may be formed of a glass material, but are not limited thereto.

At least one of the first lens 610 and the second lens 620 may contain a light-reflective material. The light-reflective material may include, for example, at least one material selected from the group consisting of SiO₂, TiO₂, and Al₂O₃.

A content of the light-reflective material may be in the range of 3% to 15%. When the content of the light-reflective material is less than 3%, there is a problem in that a light-spreading effect is not obtained since light is not sufficiently spread. In addition, when the content of the light-reflective material is more than 15%, the amount of light emitted to the outside through the optical device 600 may be reduced, and thus light-extraction efficiency may be decreased.

The optical device 600 may be formed by injecting a fluidal solvent into a mold and solidifying the fluidal solvent. For example, the second lens 620 may be formed by injection molding, transfer molding, compression molding, or the like, and the first lens 610 filling the hollow 621 may be formed by injecting the fluidal solvent into the hollow 321 using the second lens 620 as a mold and solidifying the fluidal solvent. Also, the first lens 610 may be formed by injecting a fluidal solvent into the hollow 621 and solidifying the fluidal solvent while the light-emitting device 500 is embedded within the fluidal solvent.

The optical device 600 formed in such a method may have a structure in which the first lens 610 and the second lens 620 are integrally formed.

Meanwhile, a refractive index of the first lens 610 may be the same as or greater than that of the wavelength-converting layer 530 of the light-emitting device 500, and refractive index of the second lens 620 may be the same as or greater than that of the first lens 610.

A method of fabricating a light source module according to an exemplary embodiment of the present disclosure will be described with reference to FIGS. 10 to 14.

As illustrated in FIG. 10, a substrate 100 including a plurality of light-emitting devices 200 may be prepared. The substrate 100 may be, for example, an FR-4 type PCB or a flexible PCB that can be easily deformed, or a metal substrate, such as MCPCB or MCCL.

The substrate 100 may have in various shapes corresponding to, for example, conditions of design required in a lighting apparatus. The substrate 100 according to the exemplary embodiment of the present disclosure may have a square-shaped plate structure, but is not limited thereto. For example, the substrate 100 may have a flat plate structure having a circular shape or a bar-shape extending in one direction. In addition, the substrate 100 may have another structure having various shapes.

The plurality of the light-emitting devices 200 may be mounted and arranged on the substrate 100. Conditions of arrangement of the plurality of light-emitting devices 200 may be variously adjusted depending on a design of a lighting apparatus to be implemented.

The plurality of light-emitting devices 200 may include a package body 220 having a reflective cup-shaped recess 221, an LED chip 210 installed in the recess 221, and a wavelength-converting layer 230 filling the recess 221 and sealing the LED chip 210, as illustrated in FIGS. 3A and 3B. The light-emitting device 200 may be substantially the same as the light-emitting device 200 illustrated in FIGS. 3A and 3B, and accordingly, detailed descriptions thereof will be omitted.

FIG. 11 illustrates a process of preparing a tray 900 including a plurality of through-holes 910 and optical devices 300 inserted into respective through-holes 910.

The tray 900 may have a structure corresponding to the shape of the substrate 100. In addition, the plurality of through-holes 910 passing through the tray 900 may be arranged corresponding to respective locations of the plurality of light-emitting devices 200 arranged on the substrate 100.

Each optical device 300 may be fixedly inserted into each of the plurality of through-holes 910 to be temporarily fixed. The optical devices 300 may be inserted into the plurality of through-holes 910 such that all of the optical devices 300 face the same direction. In this case, in the optical device 300, a first surface 311 of a first lens 310 and a third surface 322 of a second lens 320, which correspond to a bottom surface of the optical device 300, and supports 330 may protrude from the through-holes 910 to be exposed.

The optical device may be substantially the same as the optical device 300 illustrated in FIGS. 1 to 4, and accordingly detailed descriptions thereof will be omitted.

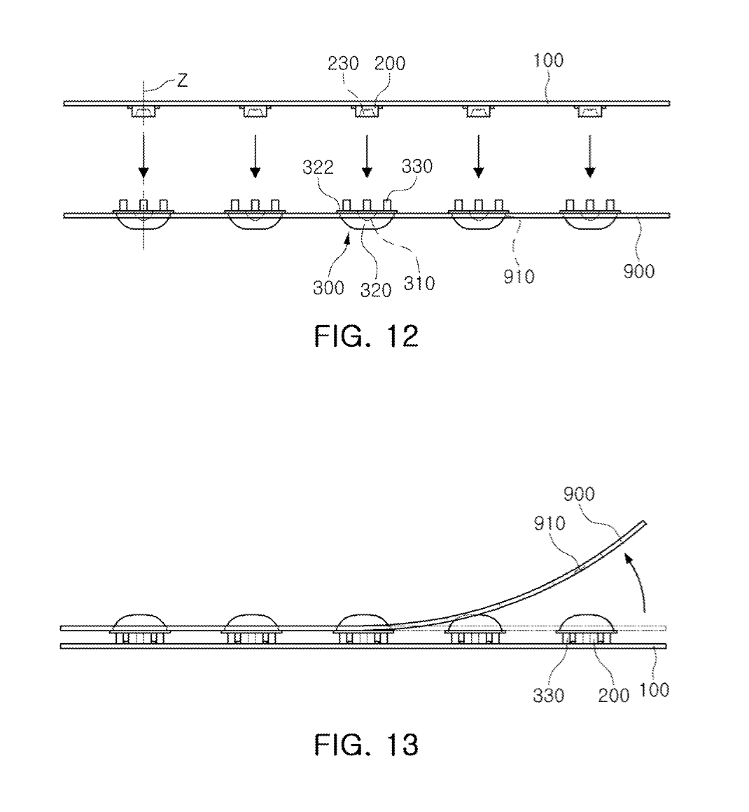

FIG. 12 illustrates a process of mounting the optical device 300 on the substrate 100.

As illustrated in FIG. 12, the tray 900 may be disposed such that a bottom surface of each optical device 300 faces up. Then, an adhesive is coated on the first surface 311 of the first lens 310 and protruding ends of the supports 330 in each optical device 300.

The adhesive may be formed of a light-transmissive material. In addition, a refractive index of the adhesive may be the same as or greater than a refractive index of the wavelength-converting layer 230 of the light-emitting device 200, and may be the same as or smaller than a refractive index of the first lens 310 of the optical device 300. The adhesive may be hardened by heat or UV irradiation.

The substrate 100 may be turned over and disposed on the tray 900 such that the plurality of light-emitting devices 200 face the tray 900. Here, each light-emitting device 200 may be disposed directly above each optical device 300 so that an optical axis of the light-emitting device 200 is aligned with a center of the optical device 300. The adjustment of position may be controlled, for example, by aligning fiducial marks (not shown) formed on the substrate 100 and the tray 900.

In such a manner, in a state in which locations of the light-emitting device 200 and the optical device 300 are adjusted to achieve one-to-one matching, the substrate 100 may be mounted on the tray 900 in such a manner that the light-emitting surface of the light-emitting device 200 is attached to the first lens 310 of the optical device 300 by an adhesive, and the substrate 100 is attached to the support 330 by an adhesive. In addition, the adhesive may be hardened by heat or UV irradiation.

FIG. 13 illustrates a process of removing the tray to be separated from the plurality of optical devices 300.

When the optical devices 300 are securely attached to substrate 100 and the light-emitting device 200 by hardening the adhesive, the tray 900 temporarily supporting the plurality of optical devices 300 may be removed.

The tray 900 may be removed, for example, by turning over the tray 900 such that the substrate 100 is located at a lower side and the tray 900 is located at an upper side, and then lifting the tray 900 such that the optical device 300 is detached from the through-holes 910.

The tray 900 may be removed in a state in which the tray 900 is located at a lower portion without inverting the substrate 100 and the tray 900.

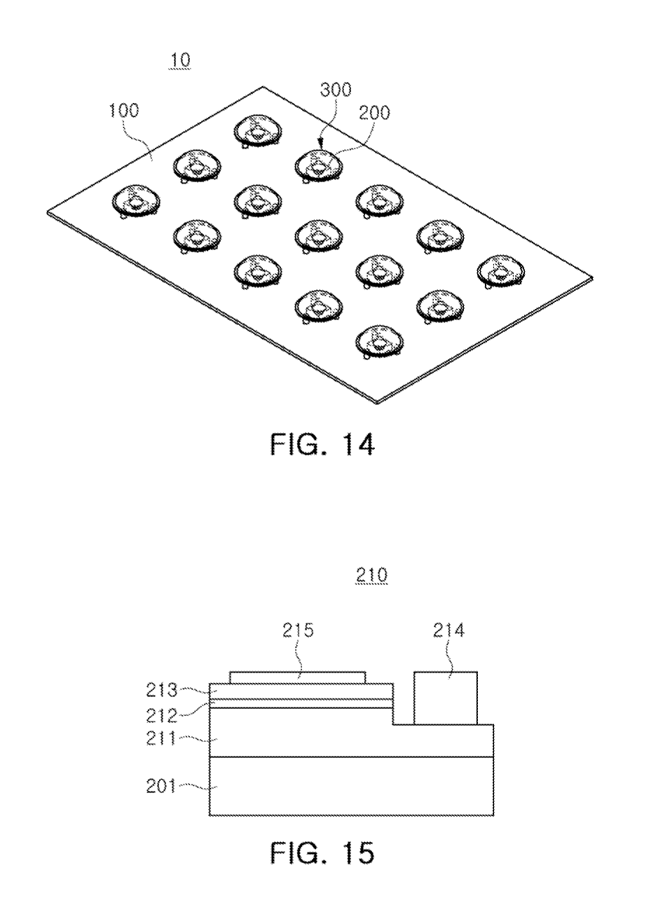

As illustrated in FIG. 14, the light source module 10 completed by removing the tray 900 may be, for example, installed in a lighting apparatus to be used as a light source.

Various exemplary embodiments of an LED chip usable in a light-emitting device will be described with reference to FIGS. 15 to 17.

Referring to FIG. 15, the LED chip 210 may include a first conductivity-type semiconductor layer 211, an active layer 212, and a second conductivity-type semiconductor layer 213, sequentially stacked on a growth substrate 201.

The first conductivity-type semiconductor layer 211 stacked on the growth substrate 201 may be an n-type nitride semiconductor layer doped with n-type impurities. In addition, the second conductivity-type semiconductor layer 213 may be a p-type nitride semiconductor layer doped with p-type impurities. However, depending on exemplary embodiments, positions of the first and second conductivity-type semiconductor layers 211 and 213 may be exchanged. Such first and second conductivity-type semiconductor layers 211 and 213 may have a compositional formula of AlₓIn_{y}Ga_{(1-x-y)}N (wherein, 0≦x<1, 0≦y<1, and 0≦x+y<1), and may be, for example, GaN, AlGaN, InGaN, and AlInGaN.

The active layer 212 disposed between the first and second conductivity-type semiconductor layers 211 and 213 may emit light having a predetermined level of energy generated by electron-hole recombination. The active layer 212 may include a material having a smaller energy bandgap than the first and second conductivity-type semiconductor layers 211 and 213. For example, when the first and second conductivity-type semiconductor layers 211 and 213 are a GaN-based compound semiconductor device, the active layer 212 may include an InGaN-based compound semiconductor device having a smaller energy bandgap than GaN. Further, the active layer 212 may have a multiple quantum well (MQW) structure, for example, an InGaN/GaN structure, in which a quantum well layer and a quantum barrier layer are alternately stacked. However, the active layer 212 may not be limited thereto, and may have a single quantum well (SQW) structure.

The LED chip 210 may include first and second electrode pads 214 and 215 electrically connected to the first and second conductivity type semiconductor layers 211 and 213, respectively. The first and second electrode pads 214 and 215 may be exposed and disposed in the same direction. In addition, the first and second electrode pads 214 and 215 may be electrically connected to a substrate by a wire bonding method or a flip-chip bonding method.

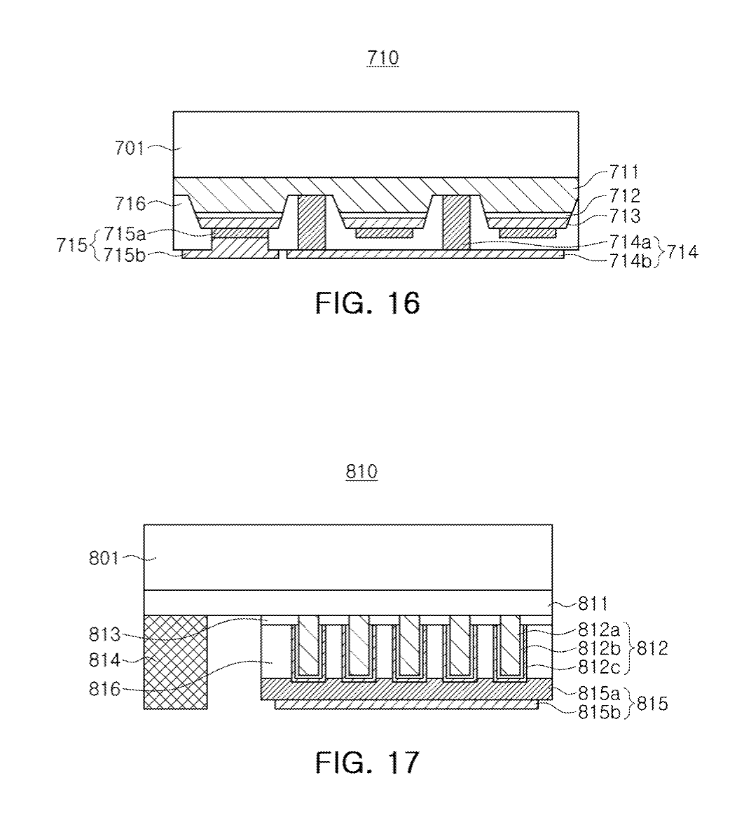

An LED chip 710 illustrated in FIG. 16 may include a stacked semiconductor structure formed on a growth substrate 701. The stacked semiconductor structure may include a first conductivity-type semiconductor layer 711, an active layer 712, and second conductivity-type semiconductor layer 713.

The LED chip 710 may include first and second electrode pads 714 and 715 respectively connected to the first and second conductivity-type semiconductor layers 711 and 713. The first electrode pad 714 may include a conductive via 714a passing through the second conductivity-type semiconductor layer 713 and the active layer 712 to be connected to the first conductivity-type semiconductor layer 711, and an electrode extension portion 714b connected to the conductive via 714a. The conductive via 714a may be surrounded by an insulating layer 716 to be electrically isolated from the active layer 712 and the second conductivity-type semiconductor layer 713. The conductive via 714a may be disposed on an area where the stacked semiconductor structure is etched. The number, shape, or pitch of the conductive via 714a, or a contact area with the first conductivity-type semiconductor layer 712 may be appropriately designed to reduce contact resistance. In addition, the conductive via 714a may be arranged in rows and columns on the stacked semiconductor structure to improve current flow. The second electrode pad 715 may include an ohmic contact layer 715a and an electrode extension portion 715b on the second conductivity-type semiconductor layer 713.

An LED chip 810 illustrated in FIG. 17 may include a growth substrate 801, a first conductivity-type semiconductor base layer 811 formed on the growth substrate 801, and a plurality of light-emitting nanostructures 812 formed on the first conductivity-type semiconductor base layer 811. In addition, the LED chip 810 may include an insulating layer 813 and a filling part 816.

The light-emitting nanostructure 812 may include a first conductivity-type semiconductor core 812a, an active layer 812b and a second conductivity-type semiconductor layer 812c, sequentially formed as shell layers on a surface of the first conductivity-type semiconductor core 812a.

In the exemplary embodiment, the light-emitting nanostructure 812 has a core-shell structure, but is not limited thereto. The light-emitting nanostructure 812 may have another structure, such as a pyramid structure. The first conductivity-type semiconductor base layer 811 may be a layer providing a growth plane for the light-emitting nanostructure 812. The insulating layer 813 may provide an open area for growing the light-emitting nanostructure 812, and may be a dielectric material, such as SiO₂ or SiNₓ. The filling part 816 may structurally stabilize the light-emitting nanostructure 812 and function to transmit or reflect light. Meanwhile, when the filling part 816 includes a light-transmitting material, the filling part 816 may be formed of a transparent material, such as SiO₂, SiNₓ, an elastic resin, silicone, an epoxy resin, a polymer, or plastic. As needed, when the filling part 816 includes a reflective material, the filling part 816 may be formed of a polymer material such as polyphthalamide (PPA), and a high reflective metal powder or a ceramic powder. The high reflective ceramic powder may be at least one selected from the group consisting of TiO₂, Al₂O₃, Nb₂O₅, and ZnO. Otherwise, the high reflective metal may be Al or silver Ag.

The first and second electrode pads 814 and 815 may be disposed on a surface of the light-emitting nanostructure 812. The first electrode pad 814 may be disposed on an exposed surface of the first conductivity-type base layer 811, and the second electrode pad 815 may include an ohmic contact layer 815a and an electrode extension portion 815b, formed under the light-emitting nanostructure 812 and the filling part 816. Otherwise, the ohmic contact layer 815a and the electrode extension portion 815b may be integrally formed.

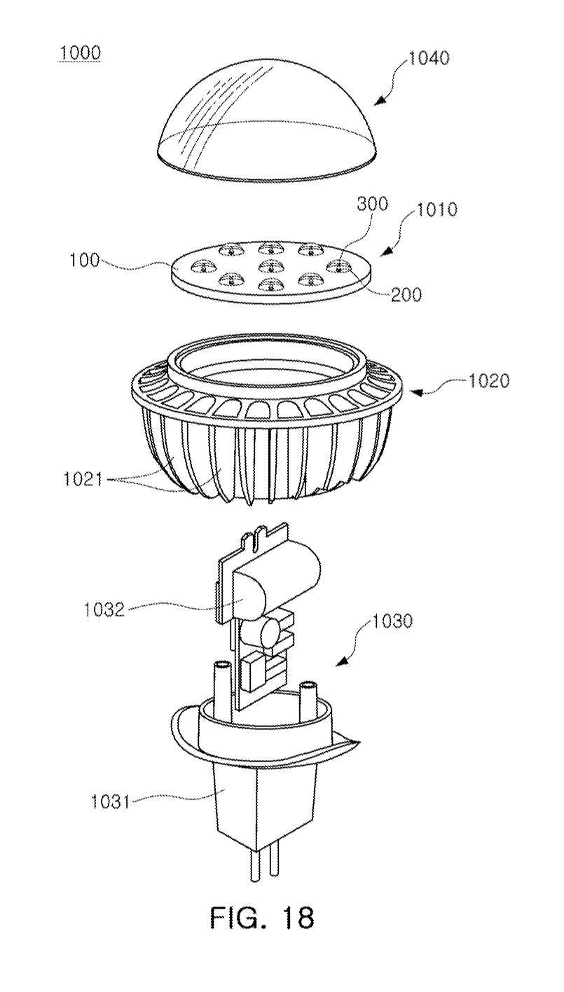

Lighting apparatuses including light source modules according to various exemplary embodiments of the present disclosure will be described with reference to FIGS. 18 to 20.

Referring to FIG. 18, a lighting apparatus 1000 according to an exemplary embodiment of the present disclosure may be a bulb-type lamp, and may be used as an indoor lighting device, for example, a downlight.

The lighting apparatus 1000 may include a housing 1020 having an electrical connection structure 1030, and a light source module 1010 mounted on the housing 1020. In addition, the lighting apparatus 1000 may further include a cover 1040 mounted on the housing 1020 and covering the light source module 1010.

Since the light source module 1010 is substantially the same as the light source module 10 illustrated in FIGS. 1 and 14, detailed descriptions thereof will be omitted.

The housing 1020 may function as a frame supporting the light source module 1010, and a heat sink emitting heat generated in the light source module 1010 to the outside. For this, the housing 1020 may be formed of a rigid material having high thermal conductivity, for example, a metal material such as Al, a heat-dissipating resin, or the like.

A plurality of heat-dissipating fins 1021 for increasing a contact area with air to improve heat-dissipating efficiency may be formed on an outer side surface of the housing 1020.

The electrical connection structure 1030 electrically connected to the light source module 1010 may be formed on the housing 1020. The electrical connection structure 1030 may include a terminal 1031, and a driver 1032 supplying driving power received through the terminal 1031 to the light source module 1010.

The terminal 1031 may allow the lighting apparatus 1000 to be installed, for example, in a socket and to be fixed and electrically connected thereto. In this exemplary embodiment, the terminal 1031 is described as having a sliding pin-type structure, but is not limited thereto. As needed, the terminal 1031 may have an Edison-type structure in which installation may be performed by turning a screw thread.

The driver 1032 may function to convert external driving power into an appropriate current source for driving the light source module and supply the converted current source. The driver 1032 may be comprised of, for example, an AC-DC converter, parts for a rectifier circuit, and a fuse. In addition, the driver 1032 may further include a communication module implementing a remote control function, as needed.

The cover 1040 may be installed in the housing 1020 to cover the at least one light source module 1010, and may have a convex lens shape or a bulb shape. The cover 1040 may be formed of a light-transmitting material, and include a light-spreading material.

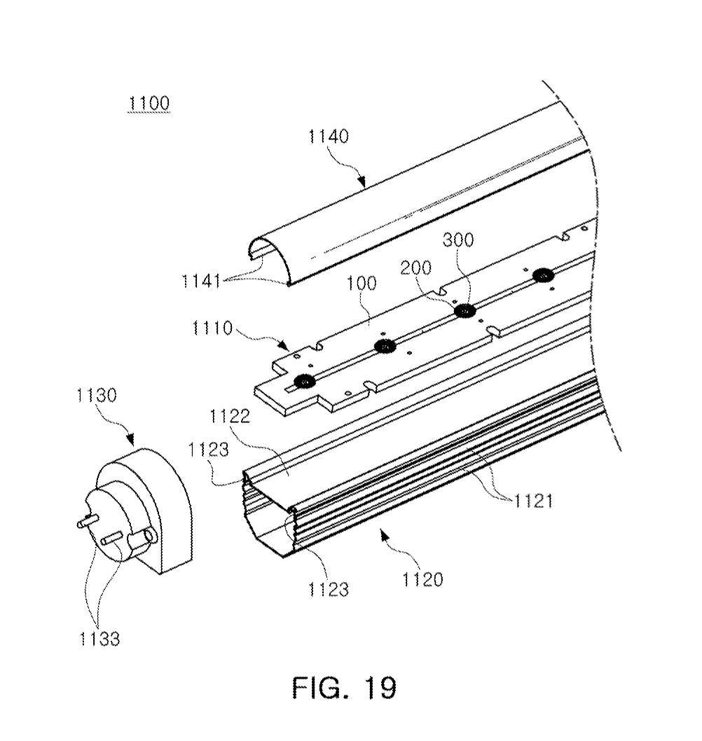

Referring to FIG. 19, a lighting apparatus 1100 may be, for example, a bar-type lamp, and may include a light source module 1110, a housing 1120, a terminal 1130, and a cover 1140.

The light source module 1110 may be substantially the same as the light source module illustrated in FIGS. 1 and 14. Accordingly, detailed descriptions thereof will be omitted.

The housing 1120 may have the light source module 1110 mounted on and fixed to one surface 1122 thereof, and release heat generated in the light source module 1110 to the outside. For this, the housing 1120 may be formed of a material having a high thermal conductivity, for example, a metal material, and a plurality of heat dissipating fins 1121 may be formed to protrude on both side surfaces thereof.

The cover 1140 may be fastened to a fastening hollow 1123 of the housing 1120 to cover the light source module 1110. In addition, the cover 1140 may have a semi-circularly curved surface so that light generated in the light source module 1110 is uniformly emitted to the outside overall. An overhanging 1141 engaged with the fastening hollow 1123 of the housing 1120 may be formed in a longitudinal direction in a bottom of the cover 1140.

The terminal 1130 may be disposed at least upon one of two end portions of the housing 1120 in the longitudinal direction to supply power to the light source module 1110. The terminal 1130 may further include an electrode pin 1133 protruding outwardly.

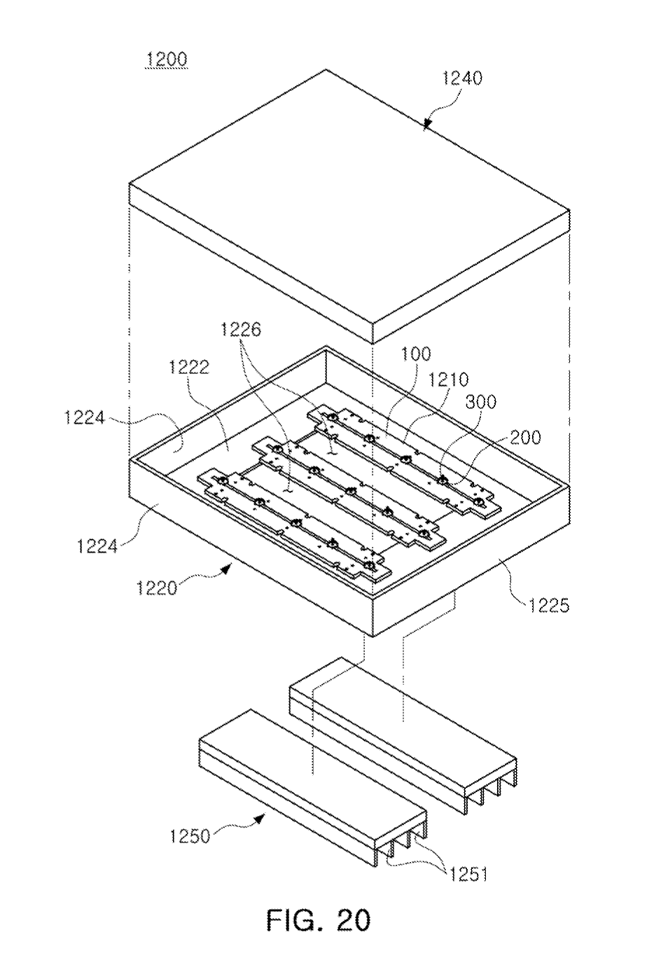

Referring to FIG. 20, a lighting apparatus 1200 may have, for example, a surface light source type structure, and include a light source module 1210, a housing 1220, a cover 1240, and a heat sink 1250.

The light source module 1210 may be substantially the same as the light source module described with reference to FIGS. 1 and 14. Accordingly, detailed descriptions thereof will be omitted.

The housing 1220 may have a box-type structure including one surface 1222 on which the light source module 1210 is mounted, and a side surface 1224 extending from edges of the one surface 1222. The housing 1220 may be formed of a material having high thermal conductivity, for example, a metal material, so as to release heat generated in the light source module 1210 to the outside.

A hole 1226 to which a heat sink 1250, to be described later, is to be inserted and engaged may be formed to pass through the one surface 1222 of the housing 1220. In addition, the light source module 1210 installed on the one surface 1222 may partially span the hole 1226 so as to be exposed to the outside.

The cover 1240 may be fastened to the housing 1220 to cover the light source module 1210. In addition, the cover 1240 may have a flat structure overall.

The heat sink 1250 may be engaged with the hole 1226 through the other surface 1225 of the housing 1220. In addition, the heat sink 1250 may be in contact with the light source module 1210 through the hole 1226 to release heat generated in the light source module 1210 to the outside. In order to increase heat dissipating efficiency, the heat sink 1250 may include a plurality of heat dissipating pins 1251. The heat sink 1250, like the housing 1220, may be formed of a material having high thermal conductivity.

Lighting apparatus using light emitting devices may be roughly divided into indoor lighting apparatuses and outdoor lighting apparatuses according to its purpose. The indoor LED lighting apparatuses may be bulb-type lamps, fluorescent lamps (LED-tubes), or flat-type lighting apparatuses, and mainly for retrofitting existing lighting apparatuses. The outdoor LED lighting apparatuses may be street lights, guard lamps, floodlights, decorative lights, or traffic lights.

In addition, the LED lighting apparatus may be utilized as interior or exterior light sources for vehicle. As the interior light source, the LED lighting apparatus may be used as various light sources for a vehicle interior lights, reading lamps, and instrument panels. As the exterior light source, the LED lighting apparatus may be used as all kinds of light sources, such as headlights, brake lights, turn indicators, fog lights, and running lights.

Further, the LED lighting apparatus may be used as a light source for robots or various types of mechanical equipment. In particular, an LED lighting apparatus using a specific wavelength band may promote the growth of plants, or stabilize mood of a person or cure diseases as an emotional lighting apparatus.

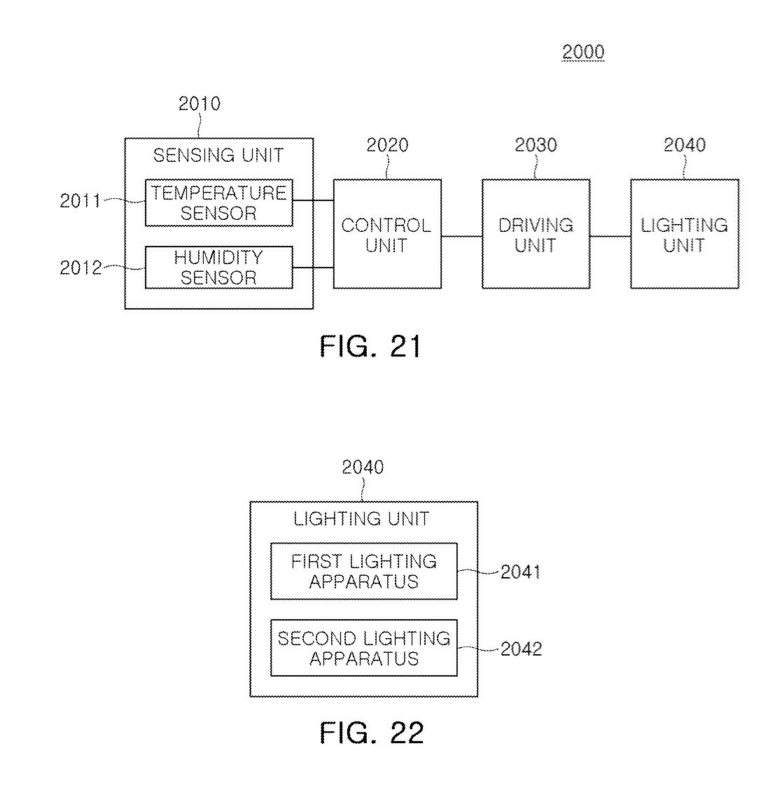

A lighting system including the above-described lighting apparatus will be described with reference to FIGS. 21 to 24. A lighting system 2000 according to an exemplary embodiment of the present disclosure may automatically control a color temperature according to an environment (for example, a temperature and a humidity) and provide not a simple lighting apparatus but an emotional lighting apparatus which meets the sensitivity of human being.

Referring to FIG. 21, the lighting system 2000 according to the exemplary embodiment of the present disclosure may include a sensing unit 2010, a control unit 2020, a driving unit 2030, and a lighting unit 2040.

The sensing unit 2010 may be installed indoors or outdoors, and include a temperature sensor 2011 and humidity sensor 2012 to measure at least one air condition between temperature and humidity of an environment. In addition, the sensing unit 2010 may send the measured air condition, that is, temperature and humidity to the control unit 2020 electrically connected thereto.

The control unit 2020 may compare the measured air temperature and humidity with air conditions (ranges of temperature and humidity) preset by users, and then determine a color temperature of a lighting unit 2040 corresponding to the air condition, based on a comparison result. The control unit 2020 may be electrically connected to the driving unit 2030, and control the driving unit 2030 to drive the lighting unit 2040 to be at the determined color temperature.

The lighting unit 2040 may be operated according to power supplied by the driving unit 2030. The lighting unit 2040 may include at least one lighting apparatus illustrated in FIGS. 18 to 20. For example, the lighting unit 2040 may include, as illustrated in FIG. 22, a first lighting apparatus 2041 and a second lighting apparatus 2042, having different respective color temperatures, and each of the lighting apparatuses 2041 and 2042 may include a plurality of light emitting devices emitting the same white light.

The first lighting apparatus 2041 may emit white light with a first color temperature, and the second lighting apparatus 2042 may emit white light with a second color temperature. The first color temperature may be lower than the second color temperature. As another example, the first color temperature may be higher than the second color temperature. Here, a white color with a relatively low temperature may correspond to a warm white color, and a white color with a relatively high temperature may correspond to a cold white color. When power is supplied to such first and second lighting apparatuses 2041 and 2042, relative white color lights with first and second color temperatures may be emitted, and the relative white lights may be mixed to implement white light having the color temperature determined by the control unit 2020.

In detail, in the case that the first color temperature is lower than the second color temperature, when the color temperature determined by the control unit 2020 is relatively high, the mixed white light may be implemented to have the determined color temperature by decreasing the light emission amount of the first lighting apparatus 2041 and increasing the light emission amount of the second lighting apparatus 2042. As another example, when the color temperature determined by the control unit 2020 is relatively low, the mixed white light may be implemented to have the determined color temperature by increasing the light emission amount of the first lighting apparatus 2041 and decreasing the light emission amount of the second lighting apparatus 2042. Here, each light emission amount of the lighting apparatuses 2041 and 2042 may be implemented by adjusting the light emission amount by adjusting power, or by adjusting the number of driven light emitting devices.

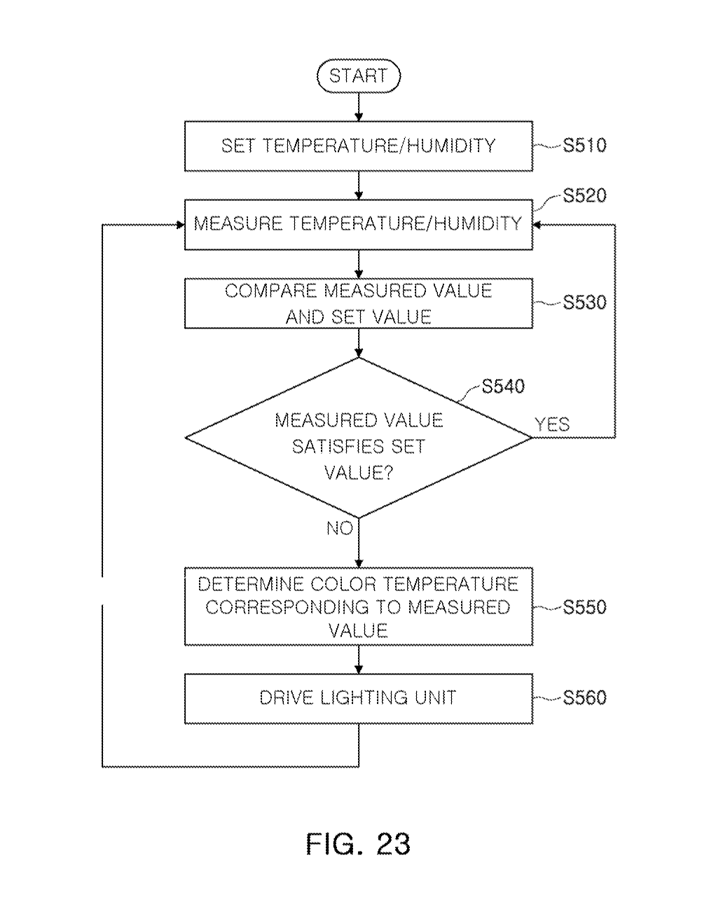

FIG. 23 is a flowchart illustrating a method of controlling the lighting system illustrated in FIG. 21. Referring to FIG. 23, first, a user sets a color temperature according to ranges of a temperature and a humidity using the control unit 2020 (S510). The set temperature and humidity data may be stored in the control unit 2020.

Normally, a cool feeling color may be produced when the color temperature is about 6000K or more, and a warm feeling color may be produced when the color temperature is about 4000K or less. According to the exemplary embodiment of the present disclosure, when the temperature and humidity are respectively higher than 20° C. and 60%, the user sets the lighting unit 2040 to be lit at a color temperature of 6000K or more, and when the temperature and humidity are respectively in the range of 10° C. to 20° C. and 40% to 60%, the user sets the lighting unit 2040 to be lit at a color temperature of 4000K to 6000K or more. Further, when the temperature and humidity are respectively lower than 10° C. and 40%, the user sets the lighting unit 2040 to be lit at a color temperature of 4000K or less.

Next, the sensing unit 2010 may measure at least one condition of a temperature and a humidity of an environment (S520). The temperature and humidity measured in the sensing unit 2010 may be sent to the control unit 2020.

Next, the control unit 2020 may compare the measured values received from the sensing unit 2010 with set values (S530). Here, the measured value is temperature and humidity data measured at the sensing unit 2010, and the set values are temperature and humidity data preset and stored at the control unit 2020 by the user. That is, the control unit 2020 may compare the measured temperature and humidity with the preset temperature and humidity.

As a result of the comparison, the control unit 2020 may determine if the measured values are within the range of set values or not (S540). When the measured values are within the range of the set values, the current color temperature is maintained, and the temperature and humidity are measured again (S520). When the measured values are not within the range of the set values, set values corresponding to the measured values are detected, and a color temperature corresponding thereto may be determined (S550). In addition, the control unit 2020 may control the driving unit 2030 to drive the lighting unit 2040 to be at the determined color temperature.

Then, the driving unit 2030 may drive the lighting unit 2040 to be at the determined color temperature (S560). That is, the driving unit 2030 may supply power required for driving the determined color temperature to the lighting unit 2040. Thus, the lighting unit 2040 may be at a color temperature corresponding to the temperature and humidity preset by the user according to the temperature and humidity of the environment.

Thus, the lighting system may automatically control a color temperature of an interior lighting unit according to the change of a temperature and a humidity of an environment, meet the sensitivity of human being through changing according to changes of a natural environment, and provide mental stability.

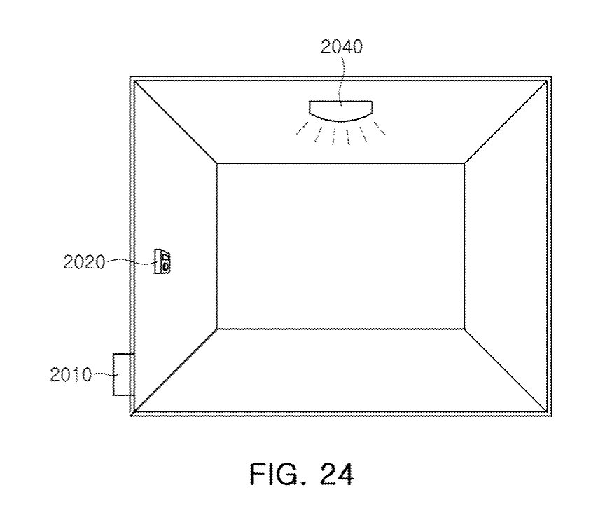

As illustrated in FIG. 24, a lighting unit 2040 may be installed on a ceiling as an indoor lighting. Here, a sensing unit 2010 may be implemented as a separated individual device and installed on an outer wall in order to measure a temperature and humidity of ambient air. In addition, a control unit 2020 may be installed indoors in order to facilitate setting and checking by a user. However, the lighting system according to the exemplary embodiment of the present disclosure may not be limited thereto, and may be installed on a wall instead of an interior lighting, and applicable to any lighting used in both indoor and outdoor, such as a lamp for example.

Optical designs of the above-described lighting apparatuses using LEDs may change depending on the product type, location, and purpose. For example, with respect to the above-described emotional lighting, there is a technique for controlling the lighting by wireless (remote) control using a mobile apparatus such as a smart-phone, in addition to technique for controlling the color, temperature, and brightness of the lighting.

In addition, there is a visible-light wireless communications technology in which the original purpose of an LED light source and a purpose as communication means can be achieved at the same time by adding a communication function to the LED lighting devices and display apparatuses. This is because the LED light source has longer lifespan than other light sources in the field, has excellent power efficiency, and implements a variety of colors. Further, the LED light source has advantages in which a switching speed for digital communication is high, and digital control is available.

The visible-light wireless communications technology is a technology for wirelessly transmitting information using light in a visible-light wavelength band, which can be perceived by the human eye. Such visible-light wireless communications technology is distinct from wired communications technology and infrared-light wireless communications technology because it uses light in a visible-light wavelength band. Further, the visible-light wireless communications technology is distinct from the wired communications technology because it uses a wireless communications environment.

In addition, differently from radio frequency (RF) wireless communications, the visible-light wireless communications technology has convenience in using frequencies because it can be freely used without restrictions or authorization, is physically secure, and has a difference in that users can visually confirm a communication link. Most of all, the visible-light wireless communications technology has a feature as fusion technology in which the original purpose of a light source and communication functions can be achieved at the same time.

As set forth above, according to exemplary embodiments of the present disclosure, a light source module and a lighting apparatus may be provided.

While exemplary embodiments have been shown and described above, it will be apparent to those skilled in the art that modifications and variations could be made without departing from the scope of the present disclosure as defined by the appended claims.

What is claimed is:

1. A light source module, comprising:
a substrate;
at least one light-emitting device mounted on the substrate; and
at least one optical device mounted on the substrate and covering the at least one light-emitting device,
wherein the optical device comprises a first lens covering a light-emitting surface of the light-emitting device and a second lens covering the first lens.

2. The light source module of claim 1, wherein the first lens comprises a first surface disposed on the light-emitting surface of the light-emitting device and on which light is incident from the light-emitting surface, and a second surface connected to an edge of the first surface and protruding in a light-emitting direction, and
the second lens comprises a third surface facing the light-emitting device and having a hollow accommodating the first lens in a center thereof, and a fourth surface disposed on the second surface, connected to an edge of the third surface, and emitting the light.

3. The light source module of claim 2, wherein the first surface and the second surface are disposed on a level corresponding to each other.

4. The light source module of claim 2, wherein a cross-sectional area of the first surface is the same as or greater than a cross-sectional area of the light-emitting surface of the light-emitting device.

5. The light source module of claim 2, wherein the first lens is embedded in the second lens in the manner of filling the hollow, and the first lens is integrated with the second lens.

6. The light source module of claim 2, wherein the fourth surface comprises a first curved surface recessed toward the hollow on an optical axis and having a concave surface and a second curved surface having a convex surface continuously extending from an edge of the first curved surface to an edge connected to the third surface.

7. The light source module of claim 1, wherein at least one of the first lens and the second lens comprises a light-reflecting material.

8. The light source module of claim 1, wherein a refractive index of the second lens is the same as or greater than a refractive index of the first lens.

9. The light source module of claim 1, wherein the at least one light-emitting device comprises a package body having a reflective cup-shaped recess, an LED chip installed in the recess, and a wavelength-converting layer filling the recess and sealing the LED chip.

10. The light source module of claim 1, wherein the optical device comprises a support protruding from the second lens.

11. The light source module of claim 10, wherein the support has a length corresponding to a height of the light-emitting device.

12. A light source module, comprising:
a substrate;
at least one light-emitting device mounted on the substrate;
at least one first lens mounted on the substrate and covering the at least one light-emitting device; and
at least one second lens mounted on the substrate and covering the at least one first lens,
wherein the first lens is embedded in the second lens and integrated with the second lens.

13. The light source module of claim 12, wherein the first lens comprises a first surface disposed on the substrate, and a second surface connected to an edge of the first surface and protruding in a light-emitting direction, and
the second lens comprises a third surface disposed on the substrate and including a hollow accommodating the first lens in a center thereof, a fourth surface disposed on the second surface and emitting light of the light-emitting device to the outside, and a fifth surface connecting edges of the third surface and the fourth surface and reflecting the light to the fourth surface.

14. The light source module of claim 13, wherein the fifth surface forms an obtuse angle with respect to the third surface, and is inclined with respect to the third surface.

15. The light source module of claim 13, wherein the second lens further comprises a reflective layer covering the fifth surface.

16. The light source module of claim 13, wherein the fourth surface is bulged in the light-emitting direction.

17. The light source module of claim 13, wherein at least one of the hollow and the fourth surface comprises ridges.

18. The light source module of claim 12, wherein the at least one light-emitting device comprises a package body having a reflective cup-shaped recess, an LED chip installed in the recess, and a wavelength-converting layer filling the recess and sealing the LED chip, and
the wavelength-converting layer includes at least one phosphor material.

19. The light source module of claim 18, wherein a refractive index of the first lens is the same as or greater than a refractive index of the wavelength-converting layer, and
a refractive index of the second lens is the same as or greater than that of the first lens.

20. A lighting apparatus, comprising:
a housing having an electrically connected structure; and
at least one light-emitting module installed in the housing,
wherein the at least one light-emitting module comprises:
a substrate;
at least one light-emitting device mounted on the substrate; and
at least one optical device mounted on the substrate and covering the at least one light-emitting device,
wherein the optical device comprises a first lens covering a light-emitting surface of the light-emitting device and a second lens covering the first lens.
